(19) United States
(12) Patent Application Publication
(10) Pub. No.: US 2005/0224983 A1
(43) Pub. Date: Oct. 13, 2005

(54) Semiconductor structures and methods for forming patterns using nitrogen-free SiCOH anti-reflective layers

(76) Inventors: Won-jin Kim, Gyeonggi-do (KR); Hyun Park, Gyeonggi-do (KR); Chang-seob Kim, Gyeonggi-do (KR); Mun-jun Kim, Gyeonggi-do (KR); Hye-min Kim, Gyeonggi-do (KR); Jin-gyun Kim, Gyeonggi-do (KR)

Correspondence Address: MYERS BIGEL SIBLEY & SAJOVEC, PO BOX 37428, RALEIGH, NC, 27627, US

(21) Appl. No.: 10/973,165

(22) Filed: Oct. 26, 2004

(30) Foreign Application Priority Data
Apr. 7, 2004 (KR) 2004-0023811

(51) Int. Cl. H01L 21/00

(52) U.S. Cl. 257/758

(57) ABSTRACT

A semiconductor structure includes a material layer on a substrate and to be patterned, an amorphous carbon layer on the material layer to be patterned, an N-free anti-reflective layer on the amorphous carbon layer, and a photoresist layer on the N-free anti-reflective layer. The N-free anti-reflective layer contains SiC_{X}O_{Y}H_{Z} as a main element. Related methods of patterning semiconductor structures also are provided.

### RELATED APPLICATION

This application claims the benefit under 35 U.S.C. § 119 of Korean Patent Application No. 2004-23811, filed on Apr. 7, 2004, in the Korean Intellectual Property Office, the disclosure of which is incorporated herein by reference in its entirety as if set forth fully herein.

### FIELD OF THE INVENTION

The present invention relates to semiconductor structures and methods for fabricating the same, and more particularly, to patterned semiconductor structures and methods of forming patterns in semiconductor structures.

### BACKGROUND OF THE INVENTION

As the integration density of semiconductor devices increases, the critical dimension (CD) of patterns generally decreases. Thus, to precisely form fine patterns, deep ultraviolet rays have been used as an exposure source for a photolithography process. The deep ultraviolet rays have a high resolution, but may make it difficult to form a thick photoresist layer. Accordingly, a hard mask, which is formed of a solid material, may be used as an etch mask instead of the photoresist layer. A conventional hard mask is typically formed of oxide, nitride, polysilicon, or amorphous carbon. However, if the hard mask is formed of oxide, nitride, or polysilicon, the hard mask may need to be removed using chemical mechanical polishing (CMP) or a dry etching process. For this and/or other reasons, a hard mask formed of amorphous carbon has been used.

For example, by using a double layer of an amorphous carbon layer and a layer formed of the same material as an etching target layer, i.e., a capping layer, as a hard mask, fine patterns can be formed. The amorphous carbon layer can be used not only as an anti-reflective layer but also an etch mask for finely patterning a material layer (e.g., an oxide layer). Since the amorphous carbon layer may be easily removed by an ashing process after desired patterns are formed, an additional process for removing the amorphous carbon layer, such as CMP or dry etching, may not be needed.

FIGS. 1 through 5 are cross-sectional views illustrating conventional methods of forming patterns of a semiconductor device using a conventional hard mask structure including an amorphous carbon layer.

Referring to FIG. 1, a material layer to be patterned, for example, an oxide layer 101, is formed on a substrate 100. The substrate can comprise single crystal semiconductor, such as silicon, compound semiconductor and/or non-semiconductor materials, such as glass. An amorphous carbon layer 102 and a capping oxide layer 104 are sequentially formed as a hard mask on the semiconductor substrate 100 where the oxide layer 101 is formed, and an organic anti-reflective coating layer 106 and a photoresist layer 108 are formed thereon. The capping oxide layer 104 may be a plasma-enhanced SiO₂ (PE-SiO₂) layer or a plasma enhanced TEOS(PE-TEOS) layer. The photoresist layer 108 may be, for example, a photoresist layer for ArF exposure.

Referring to FIG. 2, a photoresist pattern 108a is formed by patterning the photoresist layer 108 using photolithography, and the organic anti-reflective coating layer 106 and the capping oxide layer 104 are selectively etched using the photoresist pattern 108a as an etch mask, thereby forming an organic anti-reflective coating pattern 106a and a capping oxide pattern 104a.

Referring to FIG. 3, the amorphous carbon layer 102 is etched using the capping oxide pattern 104a as an etch mask, thereby forming an amorphous carbon pattern 102a. At this time, the photoresist pattern 108a is also removed.

Referring to FIG. 4, the oxide layer 101 is selectively etched using the capping oxide pattern 104a and the amorphous carbon pattern 102a as an etch mask, thereby forming a desired oxide pattern 101a. While the oxide layer 101 is being etched, the capping oxide pattern 104a, which is formed of substantially the same material as the oxide layer 101, is also removed. Accordingly, after the patterns are formed, it is not necessary to perform an additional process, such as CMP, to remove the capping oxide pattern 104a.

Referring to FIG. 5, the remaining amorphous carbon pattern 102a is completely removed using ashing and wet stripping. Therefore, a subsequent process for removing the capping oxide pattern 104a can be omitted.

However, this amorphous carbon layer 102 may be easily damaged by O₂-plasma generated during ashing for photo rework. Specifically, when CD failures, misalignment, or pattern failures are found by after develop inspection (ADI), a previously coated photoresist layer should be removed, and a photolithography process should be performed again. This is called photo rework. The photo rework may necessitate O₂-plasma ashing to remove the previous photoresist layer. Here, O₂-plasma may diffuse into the amorphous carbon layer, such that the amorphous carbon layer may be partially damaged. This appears to be because the PE-SiO₂ or PE-TEOS constituting the capping oxide layer 104 has a high oxygen transmissivity. In particular, when the amorphous carbon layer contains some particles, the capping oxide layer apparently does not completely cover the amorphous carbon layer, thus allowing oxygen to easily diffuse into the amorphous carbon layer.

FIG. 6 is a cross-sectional view of a conventional hard mask structure, which is ashed for photo rework. A stack structure shown in FIG. 6 is obtained by removing a previously coated photoresist layer 108 using ashing for photo rework and coating a new photoresist layer 108′.

Referring to FIG. 6, during ashing for removing the existing photoresist layer 108, an oxygen diffusion path 60 appears to be produced in the capping oxide layer 140 so that a partially damaged portion 151 is generated in the amorphous carbon layer 102 due to O₂-plasma. As a result, the amorphous carbon layer 102 may not serve as an etch mask in the partially damaged portion 151. Where the oxide layer 101 disposed on the substrate 100 is patterned, a portion of the oxide layer 101, which is disposed directly under the damaged portion 151, is removed to cause pattern failures. In particular, when the amorphous carbon layer 102 contains some particles, partial damage of the amorphous carbon layer 102 may grow worse.

FIGS. 7 and 8 are cross-sectional views illustrating damage of the amorphous carbon layer due to ashing for photo rework in the conventional hard mask structure.

Referring to FIG. 7, once a particle 50 is lodged in the amorphous carbon layer 102, an amorphous carbon layer 102c and a capping oxide layer 104c may be incompletely formed on the particle 50. Thus, referring to FIG. 7, portions of sidewalls of the particle 50 may be exposed. Then, if an ashing process for photo rework is performed, O₂-plasma may easily diffuse into the amorphous carbon layer 102 through the exposed sidewalls of the particle 50. As a result, the amorphous carbon layer 102 may be damaged. If the amorphous carbon layer 102 is excessively damaged, as shown in FIG. 8, a portion of the amorphous carbon layer 102 and a portion of the capping oxide layer 104 around the particle 50 may be removed. When patterns are formed on the damaged resultant structure after photo rework, the oxide layer 101 around the particle 50 may be completely etched and may cause an annular pattern failure 150.

FIGS. 9 and 10 are scanning electronic microscope (SEM) images of pattern failures resulting from the photo rework using the conventional hard mask. As shown in FIGS. 9 and 10, which are plan views of patterns, the pattern failures have annular shapes. A particle is located in the center of each annulus, and an adjacent portion to the particle is completely etched to expose patterns under the oxide layer 101.

### SUMMARY OF THE INVENTION

According to some embodiments of the present invention, there is provided a semiconductor structure including a material layer to be patterned on a substrate, an amorphous carbon layer on the material layer to be patterned, an N-free anti-reflective layer on the amorphous carbon layer, and a photoresist layer on the N-free anti-reflective layer. The N-free anti-reflective layer includes SiC_{X}O_{Y}H_{Z} as a main element. SiC_{X}O_{Y}H_{Z} may also be referred to herein as SiCOH. In some embodiments, the material layer to be patterned may be an oxide layer.

The N-free anti-reflective layer may include Si having about 2-3×10²² atoms/cm³, C having about 5-6×10¹⁹ atoms/cm³, O having about 3-4×10²² atoms/cm³, and H having about 2-3×10²¹ atoms/cm³. The N-free anti-reflective layer may be formed by performing chemical vapor deposition (CVD) using SiH₄ gas and CO₂ gas. The CVD may be performed at a temperature in a range of about 350° C. to about 450° C. by supplying the SiH₄ gas at a flow rate in a range of about 100 sccm to about 200 sccm and the CO₂ gas at a flow rate in a range of about 500 sccm to about 3000 sccm. The N-free anti-reflective layer may have a thickness in a range of about 500 Å to about 1000 Å, and the amorphous carbon layer may have a thickness in a range of about 500 Å to about 3000 Å. The semiconductor structure may further include an organic anti-reflective coating layer disposed between the N-free anti-reflective layer and the photoresist layer.

In other embodiments of the present invention, a semiconductor structure includes a material layer on a substrate, an amorphous carbon layer on the material layer, an N-free layer comprising SiCOH on the amorphous carbon layer, and a photoresist layer on the N-free layer comprising SiCOH. In some embodiments, the material layer comprises an oxide. The N-free layer comprising SiCOH may be formed as described above.

According to other embodiments of the present invention, patterns of a semiconductor device are formed by forming an amorphous carbon layer on a material layer disposed on a substrate, forming an N-free anti-reflective layer including SiC_{X}O_{Y}H_{Z} as a main element on the amorphous carbon layer, and forming a photoresist layer on the N-free anti-reflective layer. Successive etching of the photoresist layer, the N-free layer, the amorphous carbon layer and the material layer are then performed. Successive etching may be performed, in some embodiments, by forming a photoresist pattern by patterning the photoresist layer, forming an N-free anti-reflective pattern by selectively etching the N-free anti-reflective layer using the photoresist pattern as an etch mask, forming an amorphous carbon pattern by selectively etching the amorphous carbon layer using the N-free anti-reflective pattern as an etch mask, and forming patterns on the material layer by selectively etching the material layer using the N-free anti-reflective layer and the amorphous carbon pattern. In some embodiments, the material layer may be formed of oxide.

The N-free anti-reflective layer may comprise Si having about 2-3×10²² atoms/cm³, C having about 5-6×10¹⁹ atoms/cm³, O having about 3-4×10²² atoms/cm³, and H having about 2-3×10²¹ atoms/cm³. The N-free anti-reflective layer may be formed using CVD at a temperature in a range of about 350° C. to about 450° C. by supplying SiH₄ gas at a flow rate in a range of about 100 sccm to about 200 sccm and CO₂ gas at a flow rate in a range of about 500 sccm to about 3000 sccm. The N-free anti-reflective layer may be formed to a thickness in a range of about 500 Å to about 1000 Å.

Also, the amorphous carbon layer may be formed using CVD at a temperature in a range of about 400° C. to about 600° C. by supplying C₃H₆ gas at a flow rate of about 1600 sccm and He gas at a flow rate in a range of about 500 sccm to about 800 sccm. The amorphous carbon layer may be formed to a thickness in a range of about 500 Å to about 3000 Å. In some embodiments, an organic anti-reflective coating layer may be further formed between the forming of the N-free anti-reflective layer and the forming of the photoresist layer.

### BRIEF DESCRIPTION OF THE DRAWINGS

FIGS. 1 through 5 are cross-sectional views illustrating conventional methods of forming patterns using a conventional hard mask structure including an amorphous carbon layer;

FIG. 6 is a cross-sectional view of the conventional hard mask structure, which is ashed for photo rework;

FIGS. 7 and 8 are cross-sectional views illustrating damage of the amorphous carbon layer due to ashing for photo rework in the conventional hard mask structure;

FIGS. 9 and 10 are scanning electronic microscope (SEM) images of pattern failures resulting from the photo rework using a conventional hard mask; and

FIGS. 11 through 16 are cross-sectional views illustrating methods and structures for forming patterns according to embodiments of the present invention.

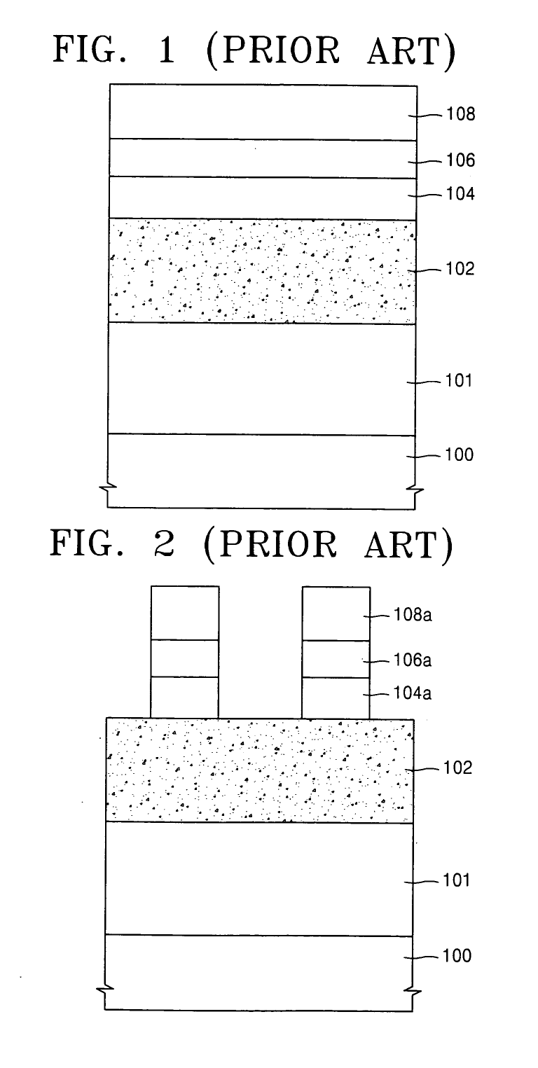

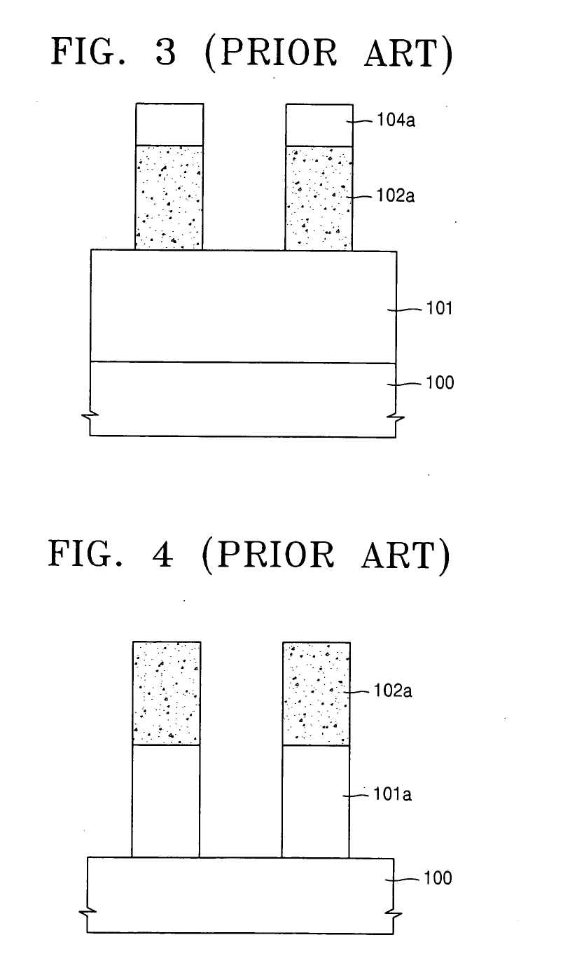

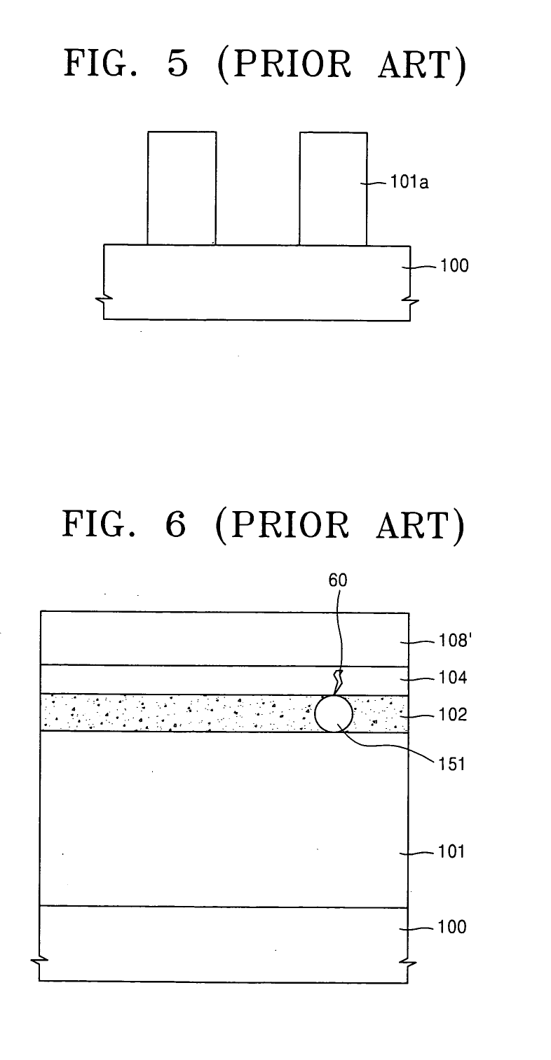

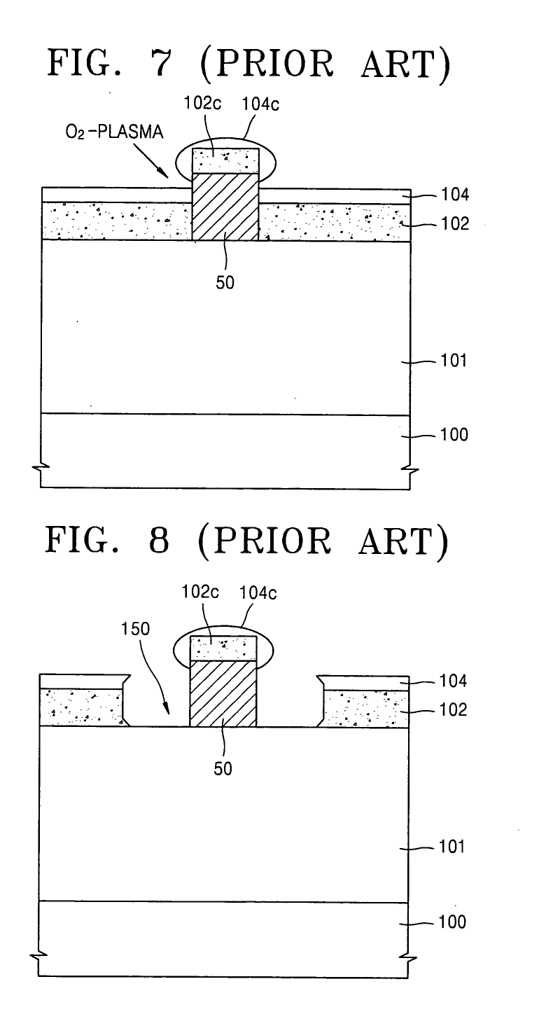

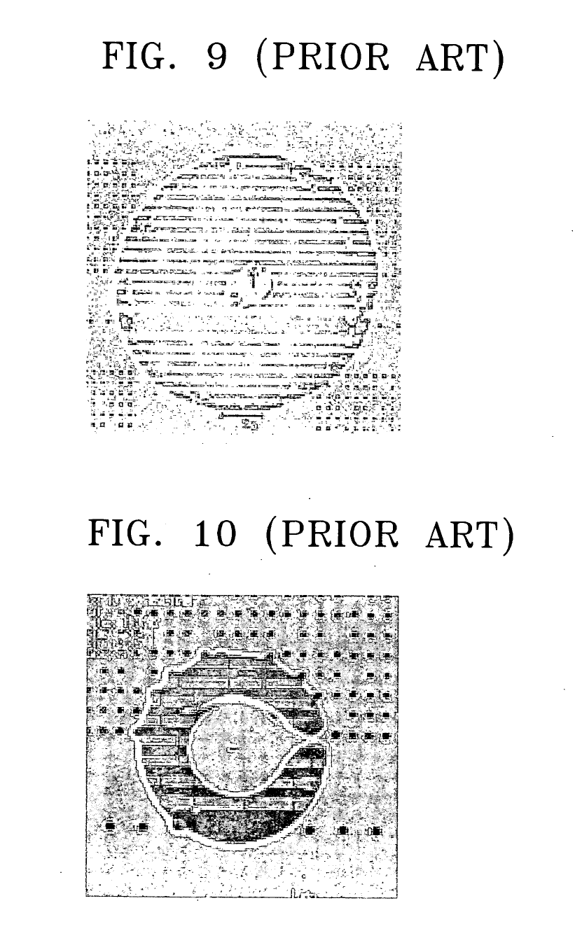

### DETAILED DESCRIPTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” another element, it can be directly on the other element or intervening elements may also be present. The term “directly on” means that there are no intervening elements. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Furthermore, relative terms such as “below” or “above” may be used herein to describe a relationship of one layer or region to another layer or region relative to a substrate or base layer as illustrated in the figures. It will be understood that these terms are intended to encompass different orientations of the device in addition to the orientation depicted in the figures. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising,” “includes” and/or “including”, specify the presence of stated features, regions, steps, operations, elements, and/or components, but do not preclude the presence or addition of one or more other features, regions, steps, operations, elements, components, and/or groups thereof.

Embodiments of the invention are described herein with reference to plan views and cross-sectional illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, sharp angles illustrated herein will, typically, have rounded corners rather than the exact shapes shown in the figures. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

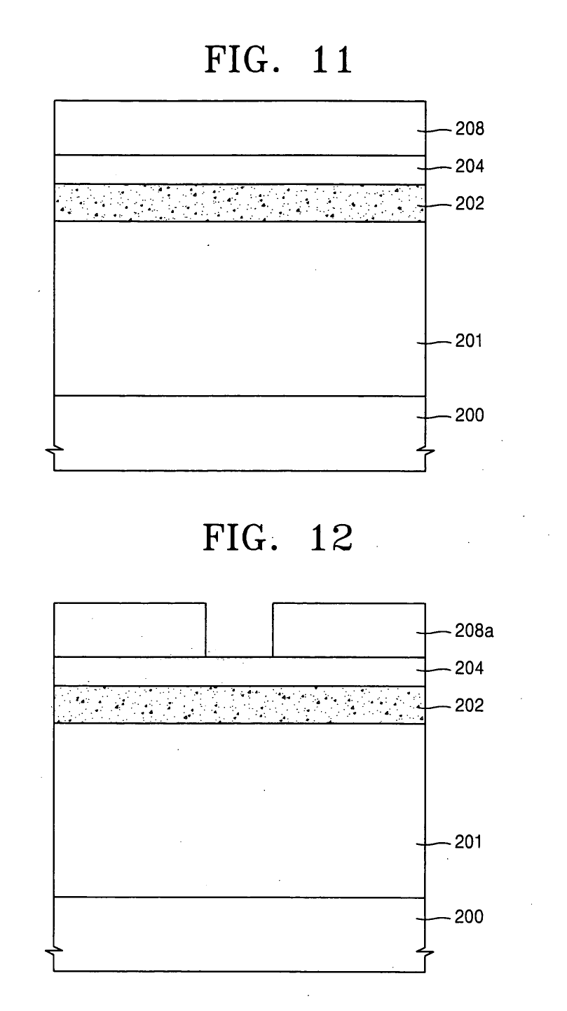

FIGS. 11 through 16 are cross-sectional views illustrating methods of forming patterns according to embodiments of the present invention, and semiconductor structures so formed according to embodiments of the present invention.

Referring to FIG. 11, to form patterns in an oxide layer 201 disposed on a substrate 200, an amorphous carbon layer 202, an N-free anti-reflective layer 204, and a photoresist layer 208 are sequentially stacked. The substrate 200 can comprise single crystal semiconductor materials such as silicon, compound semiconductor materials and/or non-semiconductor materials such as glass.

Specifically, C₃H₆ gas and He gas are supplied at a flow rate in a range of about 1200 sccm and about 650 sccm, respectively, to a process chamber accommodating the substrate 200 on which the oxide layer 201 is formed. Thus, an amorphous carbon layer 202 is deposited on the oxide layer 201 using chemical vapor deposition (CVD). The amorphous carbon layer 202 may be deposited at a temperature in a range of about 400° C. to about 600° C. to a thickness in a range of about 500 Å to about 3000 Å.

After the amorphous carbon layer 202 is deposited, SiH₄ gas and CO₂ gas are supplied at a flow rate of about 140 sccm and about 12000 sccm, respectively, to a process chamber accommodating the resultant structure. Thus, an N-free anti-reflective layer 204 is formed on the amorphous carbon layer 202 using CVD. The N-free anti-reflective layer may be deposited at a temperature of about 350° C. to about 450° C. to a thickness of about 500 Å to about 1000 Å.

The N-free anti-reflective layer 204, which results from this deposition process, contains no nitrogen or an extremely small amount of nitrogen. Even if measured using a Rutherford Backscattering Spectroscopy (RBS) or a Secondary Ion Mass Spectrometer (SIMS), the concentration of nitrogen in the N-free anti-reflective layer 204 is below the detection limit. The N-free anti-reflective layer 204 includes SiC_{X}O_{Y}H_{Z} (SiCOH) as a main element. It will be understood that x, y and z are all greater than zero. When the N-free anti-reflective layer 204 was detected using an RBS, the result was that the N-free anti-reflective layer was formed of Si having about 2.6×10²² atoms/cm³, C having about 5.6×10¹⁹ atoms/cm³. O having about 3.7×10²² atoms/cm³, and H having about 2.8×10²¹ atoms/cm³. The N-free anti-reflective layer 204 does not substantially contain nitrogen.

Referring to FIG. 12, the photoresist layer 208 is patterned using a photolithography process, thereby forming a photoresist pattern 208a. The photoresist pattern 208a may be formed using a conventional exposure and develop processes. During exposure, the N-free anti-reflective layer 204 serves to reduce or prevent reflection of an exposure source. The photoresist pattern 208a is transferred to the oxide layer 201 later to form a desired oxide pattern.

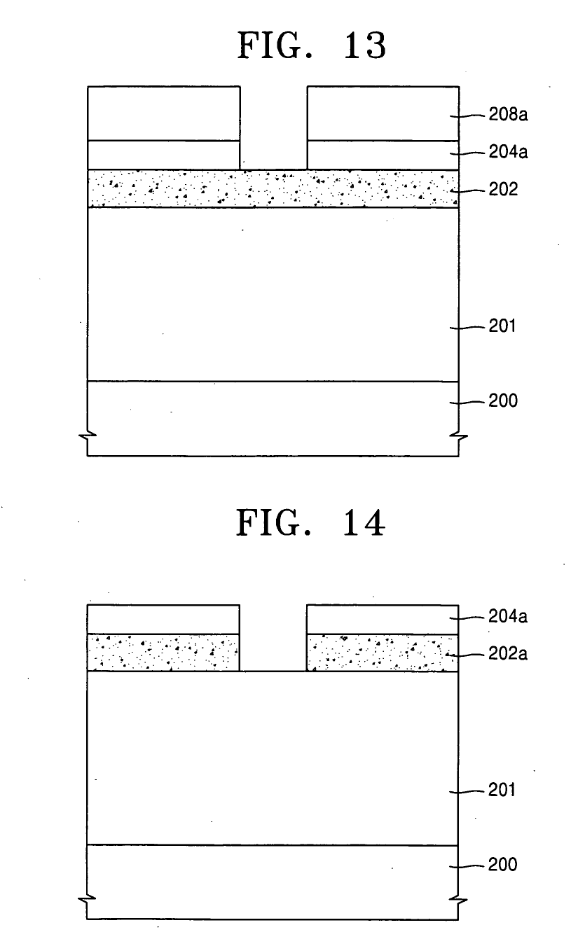

Referring to FIG. 13, the N-free anti-reflective layer 204 is selectively etched using the photoresist pattern 208a as an etch mask, thereby forming an N-free anti-reflective pattern 204a. The N-free anti-reflective pattern 204 will be used as an etch mask for selectively etching the amorphous carbon layer 202 disposed thereunder. Thus, in some embodiments of the present invention, the N-free anti-reflective layer 204 serves as not only an anti-reflective layer but also as an etch mask.

Referring to FIG. 14, the amorphous carbon layer 202 is selectively etched using the N-free anti-reflective pattern 204a as an etch mask, thereby forming an amorphous carbon pattern 202a. Since the photoresist pattern (refer to 208a of FIG. 13) is formed of carbon like the amorphous carbon layer 202, when the amorphous carbon layer 202 is selectively etched, the remaining photoresist pattern is also removed. This amorphous carbon pattern 202a along with the N-free anti-reflective pattern 204a functions as an etch mask for selectively etching the oxide layer 201 disposed thereunder.

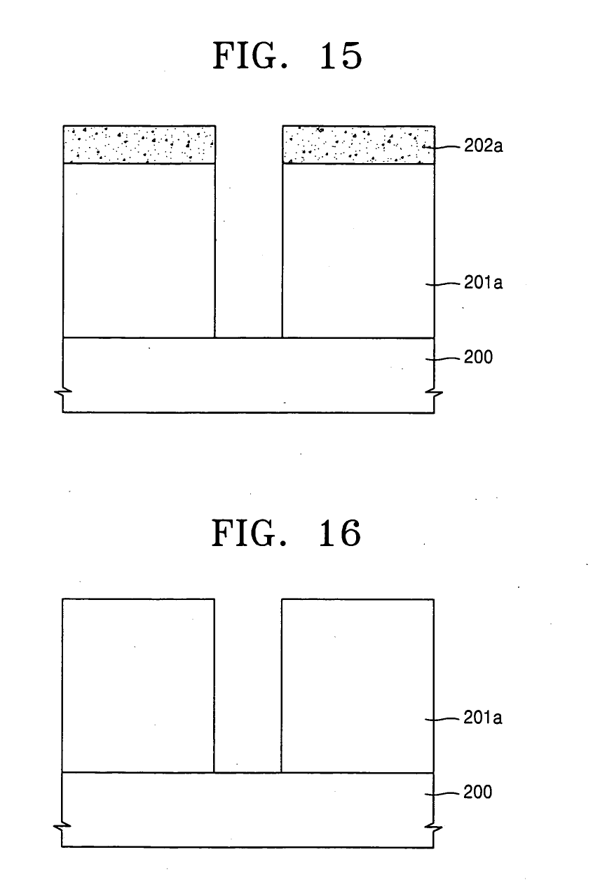

Referring to FIG. 15, the oxide layer 201 is selectively etched using the amorphous carbon pattern 202a and the N-free anti-reflective pattern 204a as an etch mask, thereby forming an oxide pattern 201a. Since SiC_{X}O_{Y}H_{Z} constituting the N-free anti-reflective pattern 204a has a similar binding structure to SiO₂ constituting the oxide layer 201, while the oxide layer 201 is being selectively etched, the N-free anti-reflective pattern 204a is also etched. Thus, the N-free anti-reflective pattern 204a is removed and simultaneously, the oxide pattern 201a is formed. Accordingly, an additional process for removing the N-free anti-reflective pattern 204a may not be needed.

Referring to FIG. 16, the remaining amorphous carbon pattern 202a may be easily removed using ashing and wet stripping. Here, a conventional ashing process, not ashing for photo rework, is performed.

As explained thus far, in embodiments of the present invention, the N-free anti-reflective layer 204 is formed on the amorphous carbon layer 202. Thus, after patterns are formed, an additional process for removing the N-free anti-reflective pattern 204a may not be needed, and reflection of the exposure source can be reduced or prevented during the exposure process.

In addition, since the N-free anti-reflective layer 204 comprising SiCOH is a dense layer, oxygen hardly diffuses into the N-free anti-reflective layer 204. In particular, if photo rework is performed for misalignment or CD failure reasons, an ashing process may be performed to remove the previously formed photoresist pattern 208a. Here, the N-free anti-reflective layer 204 can substantially reduce or prevent oxygen from diffusing into the amorphous carbon layer 202, thus protecting the amorphous carbon layer 202 from O₂-plasma. Even if the amorphous carbon layer 202 contains some particles, oxygen does not diffuse significantly into the N-free anti-reflective layer 204 compared to a conventional capping oxide layer. As a result, damage of the amorphous carbon layer 202, which is caused by oxygen diffusion during ashing for photo rework, can be reduced or minimized, and CD failures can be suppressed.

In embodiments of the present invention, patterns are formed using a double layer of an N-free anti-reflective layer comprising SiCOH and an amorphous carbon layer as a hard mask. Thus, after the patterns are formed, an additional process, such as a chemical mechanical polishing (CMP) process or a dry etching process, may need not be performed to remove the hard mask. Also, even if an ashing process for photo rework is performed, damage of the amorphous carbon layer may be reduced or suppressed so as to form precisely fine patterns. Further, reflection of the exposure source can be reduced or prevented using the hard mask during an exposure process.

In the drawings and specification, there have been disclosed embodiments of the invention and, although specific terms are employed, they are used in a generic and descriptive sense only and not for purposes of limitation, the scope of the invention being set forth in the following claims. For example, although only an N-free anti-reflective layer is used as an anti-reflective layer in the above-described embodiments, an organic anti-reflective coating layer may be additionally formed on the N-free anti-reflective layer to reinforce a reflection preventing effect during an exposure process.

1. A semiconductor structure comprising:
a material layer to be patterned on a substrate;
an amorphous carbon layer on the material layer to be patterned;
an N-free anti-reflective layer on the amorphous carbon layer; and
a photoresist layer on the N-free anti-reflective layer,
wherein the N-free anti-reflective layer includes SiC_{X}O_{Y}H_{Z} as a main element.

2. The structure of claim 1, wherein the material layer to be patterned comprises an oxide layer.

3. The structure of claim 1, wherein the N-free anti-reflective layer comprises Si having about 2-3×10²² atoms/cm³, C having about 5-6×10¹⁹ atoms/cm³, O having about 3-4×10²² atoms/cm³, and H having about 2-3×10²¹ atoms/cm³.

4. The structure of claim 1, wherein the N-free anti-reflective layer is formed by performing chemical vapor deposition using SiH₄ gas and CO₂ gas.

5. The structure of claim 4, wherein the chemical vapor deposition is performed at a temperature in a range of about 350° C. to about 450° C. by supplying the SiH₄ gas at a flow rate in a range of about 100 sccm to about 200 sccm and the CO₂ gas at a flow rate in a range of about 500 sccm to about 3000 sccm.

6. The structure of claim 1, wherein the N-free anti-reflective layer has a thickness in a range of about 500 Å to about 1000 Å, and the amorphous carbon layer has a thickness in a range of about 500 Å to about 3000 Å.

7. The structure of claim 1, further comprising an organic anti-reflective coating layer disposed between the N-free anti-reflective layer and the photoresist layer.

8. A method of forming patterns of a semiconductor device, the method comprising:
forming an amorphous carbon layer on a material layer disposed on a substrate;
forming an N-free anti-reflective layer containing SiC_{X}O_{Y}H_{Z} as a main element on the amorphous carbon layer;
forming a photoresist layer on the N-free anti-reflective layer;
forming a photoresist pattern by patterning the photoresist layer;
forming an N-free anti-reflective pattern by selectively etching the N-free anti-reflective layer using the photoresist pattern as an etch mask;
forming an amorphous carbon pattern by selectively etching the amorphous carbon layer using the N-free anti-reflective pattern as an etch mask; and
forming patterns in the material layer by selectively etching the material layer using the N-free anti-reflective layer and the amorphous carbon pattern.

9. The method of claim 8, wherein the material layer comprises oxide.

10. The method of claim 8, wherein the N-free anti-reflective layer comprises Si having about 2-3×10²² atoms/cm³, C having about 5-6×10¹⁹ atoms/cm³, O having about 3-4×10²² atoms/cm³, and H having about 2-3×10²¹ atoms/cm³.

11. The method of claim 8, wherein forming an N-free anti-reflective layer is performed using chemical vapor deposition at a temperature in a range of about 350° C. to about 450° C. by supplying SiH₄ gas at a flow rate in a range of about 100 sccm to about 200 sccm and CO₂ gas at a flow rate in a range of about 500 sccm to about 3000 sccm.

12. The method of claim 8, wherein the N-free anti-reflective layer is formed to a thickness in a range of about 500 Å to about 1000 Å.

13. The method of claim 8, wherein the forming of the amorphous carbon layer is performed using chemical vapor deposition at a temperature in a range of about 400° C. to 600° C. by supplying C₃H₆ gas at a flow rate in a range of about 1600 sccm and He gas at a flow rate in a range of about 500 sccm to 800 sccm.

14. The method of claim 8, wherein the amorphous carbon layer is formed to a thickness in a range of about 500 Å to about 3000 Å.

15. The method of claim 8, further comprising forming an organic anti-reflective coating layer between the forming of the N-free anti-reflective layer and the forming of the photoresist layer.

16. A method of forming patterns of a semiconductor device, the method comprising:
forming an amorphous carbon layer on a material layer on a substrate;
forming an N-free layer comprising SiCOH on the amorphous carbon layer;
forming a photoresist layer on the N-free layer comprising SiCOH; and
successively patterning the photoresist layer, the N-free layer comprising SiCOH, the amorphous carbon layer and the material layer.

17. The method of claim 16, wherein the material layer comprises oxide.

18. The method of claim 16, wherein the N-free layer comprising SiCOH comprises Si having about 2-3×10²² atoms/cm³, C having about 5-6×10¹⁹ atoms/cm³, O having about 3-4×10²² atoms/cm³, and H having about 2-3×10²¹ atoms/cm³.

19. The method of claim 16, wherein forming an N-free anti-reflective layer is performed using chemical vapor deposition at a temperature in a range of about 350° C. to about 450° C. by supplying SiH₄ gas at a flow rate in a range of about 100 sccm to about 200 sccm and CO₂ gas at a flow rate in a range of about 500 sccm to about 3000 sccm.

20. The method of claim 16, wherein the N-free anti-reflective layer is formed to a thickness in a range of about 500 Å to about 1000 Å.

21. A semiconductor structure comprising:
a material layer on a substrate;
an amorphous carbon layer on the material layer;
an N-free layer comprising SiCOH on the amorphous carbon layer; and
a photoresist layer on the N-free layer comprising SiCOH.

22. The structure of claim 21, wherein the material layer comprises an oxide layer.

23. The structure of claim 21, wherein the N-free layer comprising SiCOH comprises Si having about 2-3×10²² atoms/cm³, C having about 5-6×10¹⁹ atoms/cm³, O having about 3-4×10²² atoms/cm³, and H having about 2-3×10²¹ atoms/cm³.

24. The structure of claim 21, further comprising an organic layer disposed between the N-free layer comprising SiCOH and the photoresist layer.
